(19) United States
(12) Patent Application Publication
(10) Pub. No.: US 2009/0215221 A1
(43) Pub. Date: Aug. 27, 2009

(54) Image sensor and method for manufacturing the same

(75) Inventors: Jae-Ryung Yoo, Suwon-si (KR); Keun-Chan Yuk, Seoul (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/379,400

(22) Filed: Feb. 20, 2009

(30) Foreign Application Priority Data
Feb. 22, 2008 (KR) 10-2008-0016231

(51) Int. Cl. H01L 21/336; H01L 31/18

(52) U.S. Cl. 438/97; 438/305; 257/E21.409; 257/E31.079

(57) ABSTRACT

An image sensor may include a photo diode, a transfer transistor configured to transfer a photo charge generated by the photo diode to a floating diffusion region and buried channel transistors electrically coupled to the transfer transistor, wherein each of the transistors have a buried channel. The noise of the image sensor may be reduced because a channel of the buried-channel transistors in the active pixel region may be formed apart from a defected surface of a substrate when the buried-channel transistors are turned on.

### PRIORITY STATEMENT

This application claims priority under 35 USC §119 to Korean Patent Application No. 2008-0016231, filed on Feb. 22, 2008, in the Korean Intellectual Property Office (KIPO), the entire contents of which are herein incorporated by reference.

### BACKGROUND

1. Technical Field

Example embodiments relate to an image sensor, and more particularly to a complementary metal oxide semiconductor (CMOS) image sensor and a method for manufacturing an image sensor.

2. Description of the Related Art

Image sensors are semiconductor devices configured to convert an optical image into an electrical signal. Generally, there are two kinds of image sensors, namely, a charge coupled device (CCD) image sensor and a complementary metal oxide semiconductor (CMOS) image sensor.

In the CCD image sensor, metal oxide semiconductor (MOS) capacitors are arranged close to one another and charge carriers are stored in and transferred from the capacitors. On the other hand, in the CMOS image sensor, which is formed by CMOS processes, each unit pixel includes a photo diode and three or four transistors configured to drive the unit pixel. In the CMOS image sensor, a control circuit and a signal processing circuit are included as a peripheral circuit, each pixel is driven by MOS transistors, and a switching method is adopted to sequentially detect output signals.

Detailed description of the general CMOS image sensor is as follows. A unit pixel of the general CMOS image sensor comprises a photo diode configured to detect light, a transfer transistor, a reset transistor, a drive transistor and a select transistor. The transfer transistor transfers photo charges generated by the photo diode to a floating diffusion region, the reset transistor discharges charges stored in the floating diffusion region before the photo charges are transferred from the photo diode, the drive transistor operates as a source follower and the select transistor operates as a switching device to select an address.

The operation of the general CMOS image sensor described above is as follows. Initially, while the transfer transistor is turned off, light enters the photo diode so that holes and electrons are separated. The separated holes are discharged into the ground and the separated electrons are accumulated in the photo diode. The electrons accumulated in the photo diode are transferred to the floating diffusion region when the transfer transistor is turned on by applying a voltage higher than the threshold voltage to a gate of the transfer transistor. Charges stored in the floating diffusion region are discharged by the reset transistor before the charges accumulated in the photo diode are transferred to the floating diffusion region. In addition, the voltage level of the floating diffusion region is output by operating the drive transistor and the select transistor.

As described above, the general CMOS image sensor converts photo image signals into electrical signals by operating the transistors arranged in each pixel. Therefore, if incident light external to the CMOS image sensor is the same, electrons should move consistently inside the transistors in the unit pixel. However, if defects exist on the substrate on which the transistors in the unit pixel are formed, electrons cannot move consistently because charges are trapped in a gate insulator or discharged below the substrate around the defect. Consequently, even if incident light external to the CMOS image sensor is the same, output image signals may vary and a flicker noise is caused.

### SUMMARY

Example embodiments provide an image sensor that reduces a noise. Example embodiments provide a method for manufacturing the image sensor.

According to example embodiments, an image sensor may include a photo diode, a transfer transistor configured to transfer a photo charge generated by the photo diode to a floating diffusion region and buried-channel transistors electrically coupled to the transfer transistor where each of the buried-channel transistors has a buried channel.

The buried-channel transistors may include a reset transistor configured to reset the floating diffusion region by discharging charges stored in the floating diffusion region, a drive transistor configured to operate as a source follower and a select transistor configured to select address. Each of the buried-channel transistors may include a gate insulator pattern on a substrate, a gate electrode on the gate insulator pattern and a source/drain region in the substrate, and the gate electrode may include a polysilicon doped with an impurity having a different conductive type from a conductive type of an impurity in the source/drain region.

The source/drain region may be doped with an N-type impurity and the polysilicon may be doped with a P-type impurity. A hard mask pattern may be on the gate electrode. The image sensor may further include spacers along sidewalls of the gate insulator pattern, the gate electrode and the hard mask pattern. The source/drain region has a lightly doped drain (LDD) scheme including a lightly doped N-type impurity region under the spacers and a heavily doped N-type impurity region under the surface of the substrate away from the spacers. The buried channel transistors may further include a channel doping region being doped with an impurity and configured to control a threshold voltage, wherein the channel doping region may be on the buried channel of the buried-channel transistors.

The substrate may be divided into an active pixel region and a peripheral circuit region and the buried channel transistors may be located in the active pixel region. The image sensor may further include a negative channel metal oxide semiconductor (NMOS) transistor of a surface channel type in the peripheral circuit region, and a positive channel metal oxide semiconductor (PMOS) transistor of a surface channel type in the peripheral circuit region.

The NMOS transistor may include a gate insulator pattern on a substrate, a gate electrode including polysilicon doped with an N-type impurity, and a source/drain region doped with an N-type impurity. The PMOS transistor may include a gate insulator pattern on a substrate, a gate electrode including polysilicon doped with a P-type impurity, and a source/drain region doped with a P-type impurity.

The image sensor may further include a first metal silicide pattern on each of the gate electrodes, and a second metal silicide pattern, including the same material as the first metal silicide pattern, on a portion of the substrate where the source/drain region is disposed. The image sensor may further include spacers along sidewalls of the gate insulator pattern, the gate electrode and a portion of the first metal silicide pattern. The source/drain region may have a lightly doped drain (LDD) scheme including a lightly doped N-type impurity region under the spacers and a heavily doped N-type impurity region under the second metal silicide pattern. The image sensor may further include a channel doping region under the gate electrode being doped with an impurity and configured to control a threshold voltage.

According to example embodiments, a method for manufacturing an image sensor may include forming a photo diode by doping an impurity into a portion of a substrate; forming a gate insulator on the substrate; forming a polysilicon layer on the gate insulator; doping a P-type impurity into a portion of the polysilicon layer; forming a first hard mask pattern on the polysilicon layer; forming gate electrodes of a transfer transistor and buried-channel transistors by etching the polysilicon layer doped with a P-type impurity using the first hard mask pattern as an etching mask, each of the buried-channel transistors having a buried channel; and forming a first source/drain by doping an N-type impurity into the substrate away from both sides of the gate electrodes of the buried-channel transistors using the first hard mask pattern as an ion implantation mask.

The method may further include forming spacers along sidewalls of the gate insulator, the gate electrodes and the first hard mask pattern. Forming the first source/drain region may include forming a lightly doped N-type impurity region under the spacers; and forming a heavily doped N-type impurity region under the surface of the substrate away from the spacers. The method may further include forming a channel doping region on the buried channel of the buried-channel transistors by ion-implanting an impurity into the substrate to control a threshold voltage.

The method may further include forming a negative channel metal oxide semiconductor (NMOS) transistor and a positive channel metal oxide semiconductor (PMOS) transistor of a surface channel type in a peripheral circuit region, where the substrate is divided into an active pixel region and the peripheral circuit region. Forming the NMOS transistor and the PMOS transistor may include selectively ion-implanting an N-type impurity into a portion of the polysilicon layer on which the NMOS transistor is formed in the peripheral circuit region; forming a second hard mask pattern on the polysilicon layer in the peripheral circuit region; forming a gate electrode of the NMOS transistor doped with an N-type impurity and a gate electrode of the PMOS transistor doped with a P-type impurity by etching the polysilicon layer using the second hard mask pattern as an etching mask; forming a second source/drain by doping an N-type impurity into the substrate away from both sides of the gate electrode of the NMOS transistor; and forming a third source/drain by doping a P-type impurity into the substrate away from both sides of the gate electrode of the PMOS transistor.

The second hard mask pattern and the first hard mask pattern may be formed simultaneously, and the gate electrodes of the NMOS transistor, the PMOS transistor, the transfer transistor and the buried-channel transistors may be formed simultaneously. The method may further include selectively eliminating the second hard mask pattern formed on the gate electrodes of the NMOS transistor and the PMOS transistor. The method may further include forming a first metal silicide pattern on the gate electrodes of the NMOS transistor and the PMOS transistor; and forming a second metal silicide pattern on the second source/drain and the third source/drain. The first and second metal silicide patterns may be made of the same material.

The method may further include forming spacers along sidewalls of the gate insulator, the gate electrodes and a portion of the first metal silicide pattern. Forming the second and third source/drain regions may include forming a lightly doped N-type impurity region under the spacers; and forming a heavily doped N-type impurity region under the second metal silicide pattern. The method may further include forming channel doping regions under the gate electrodes being doped with an impurity to control a threshold voltage.

According to example embodiments, a method for manufacturing an image sensor may include forming a photo diode by doping an impurity into a portion of an active pixel region of a substrate; forming a gate insulator on the substrate; forming a polysilicon layer on the gate insulator; ion-implanting a P-type impurity into a portion of the polysilicon layer on which a transistor is formed in the active pixel region and into a portion of the polysilicon layer on which a positive channel metal oxide semiconductor (PMOS) transistor is formed in a peripheral circuit region; ion-implanting an N-type impurity into a portion of the polysilicon layer on which a negative channel metal oxide semiconductor (NMOS) transistor is formed in the peripheral circuit region; forming gate electrodes of a transfer transistor and buried-channel transistors in the active pixel region and gate electrodes of the NMOS transistor and the PMOS transistor in the peripheral circuit region by patterning the polysilicon layer, each of the buried-channel transistors having a buried channel; forming a first source/drain and a second source/drain by selectively doping an N-type impurity into the substrate away from both sides of the gate electrodes of the buried-channel transistors and into the substrate away from both sides of the gate electrode of the NMOS transistor respectively; and forming a third source/drain by doping selectively a P-type impurity into the substrate away from both sides of the gate electrode of the PMOS transistor.

The method may further include forming a hard mask pattern on the polysilicon layer. The method may further include selectively eliminating the hard mask pattern formed on the gate electrodes of the NMOS transistor and the PMOS transistor after forming the gate electrodes using the hard mask pattern. Selectively eliminating the hard mask pattern may include forming a first photoresist pattern covering the active pixel region; and etching the hard mask pattern in the peripheral circuit region using the first photoresist pattern as an etching mask. Forming the first source/drain and the second source/drain may include forming a second photoresist pattern selectively exposing the substrate away from both sides of the gate electrodes of the transfer transistor, the buried-channel transistors and the NMOS transistor; and ion-implanting an impurity into the substrate using the second photoresist pattern as an ion implantation mask.

In accordance with example embodiments, the flicker noise of the image sensor may be reduced because the buried channel of the transistors in the active pixel region may be formed apart from the defected surface of the substrate.

### BRIEF DESCRIPTION OF THE DRAWINGS

Example embodiments will be more clearly understood from the following detailed description taken in conjunction with the accompanying drawings. FIGS. 1-13 represent non-limiting, example embodiments as described herein.

FIG. 1 is a cross-sectional view of an image sensor according to example embodiments.

FIG. 2 is a top view of an active pixel region of an image sensor according to example embodiments.

FIG. 3 is a circuit diagram of a unit pixel of an image sensor.

FIGS. 4 to 13 are cross-sectional views illustrating a method for manufacturing an image sensor according to example embodiments.

It should be noted that these Figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION OF EXAMPLE EMBODIMENTS

Various example embodiments will be described more fully with reference to the accompanying drawings, in which some example embodiments are shown. Example embodiments may, however, be embodied in many different forms and should not be construed as limited to the embodiments set forth herein. Rather, these embodiments are provided so that this disclosure will be thorough and complete, and will fully convey the scope of example embodiments to those skilled in the art. Like reference numerals refer to like elements throughout this application.

It will be understood that, although the terms first, second, etc. may be used herein to describe various elements, these elements should not be limited by these terms. These terms are used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

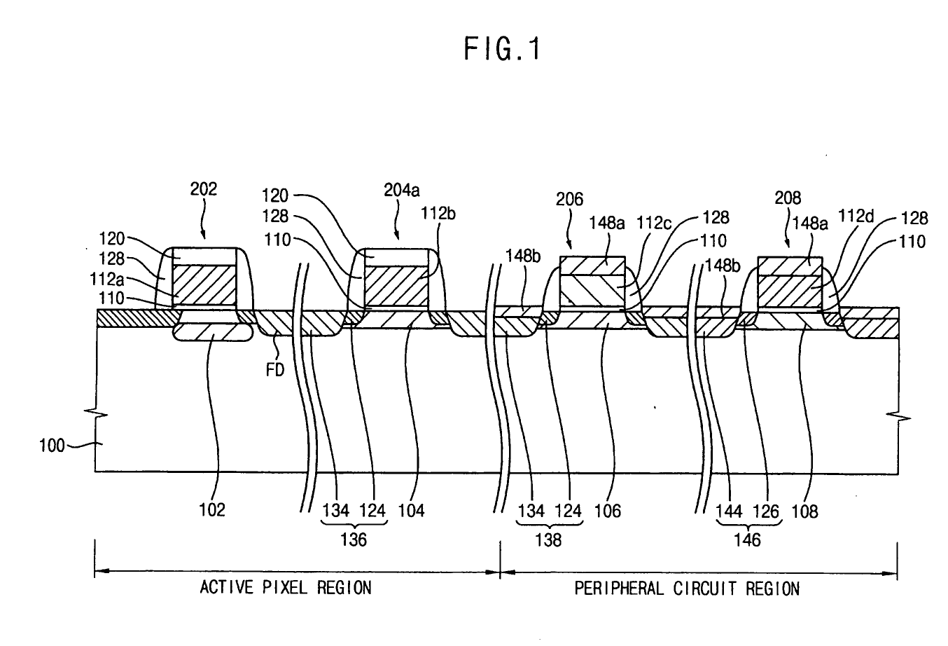

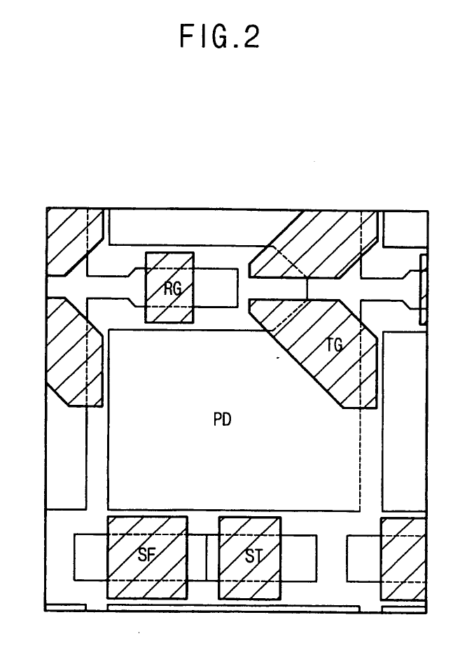

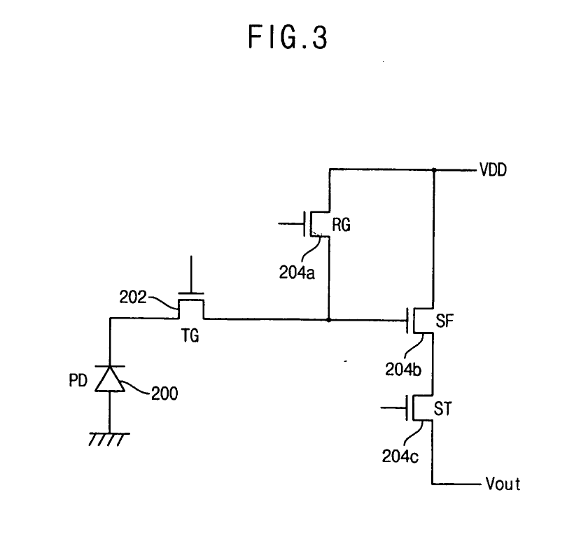

FIG. 1 is a cross-sectional view of an image sensor according to example embodiments, and FIG. 2 is a top view of an active pixel region of an image sensor according to example embodiments. FIG. 3 is a circuit diagram of a unit pixel of an image sensor.

Referring to FIGS. 1 to 3, a substrate 100 may be arranged to implement a CMOS image sensor. The substrate 100 may include an active pixel region in which elements for acquiring an image are formed and a peripheral circuit region in which elements for controlling and processing an output signal of the active pixel region are formed. The active pixel region and the peripheral circuit region of the substrate 100 may include an active region (not shown) and a device isolation region (not shown), respectively.

Unit pixels (not shown) may be arranged on the substrate 100 of the active pixel region. Each of the unit pixels may include a photo diode (PD) 200, a transfer transistor (TG) 202, a reset transistor (RG) 204a, a drive transistor (SF) 204b and a select transistor (ST) 204c. The photo diode (PD) 200 may be arranged in portions of the substrate 100 in the active pixel region to receive incident light external to the CMOS image sensor. The photo diode (PD) 200 may include a first photo diode region (not shown) partially doped with a P-type impurity below a surface of the substrate 100 and a second photo diode region (not shown) doped with an N-type impurity on the first photo diode region. The P-type impurity may include boron and the N-type impurity may include phosphorus.

The transfer transistor (TG) 202 may be arranged on one side of the photo diode (PD) 200. The transfer transistor (TG) 202 may be coupled to the photo diode (PD) 200 and may transfer a photo charge generated by the photo diode (PD) 200 to a floating diffusion region. The transfer transistor (TG) 202 may include a gate insulator 110, a first gate electrode 112a and a first channel doping region 102. Spacers 128 may be arranged on both side walls of the first gate electrode 112a. More particularly, the region of the impurity of the photo diode (PD) 200 may be extended to a portion of the substrate 100 on which a first side wall of the first gate electrode 112a is arranged. The first channel doping region 102, arranged on a portion of the substrate 100 below the first gate electrode 112a, may be doped with a P-type impurity. The first gate electrode 112a may include polysilicon doped with a P-type impurity. A hard mask pattern 120 may be arranged on the first gate electrode 112a. The hard mask pattern 120 may be used as an etching mask and an anti-reflection layer. The hard mask pattern 120 may include a silicon nitride or a silicon oxynitride.

A portion of the substrate 100 adjacent to a second side wall of the first gate electrode 112a of the transfer transistor (TG) 202 is the floating diffusion region (FD), where the second side wall is opposite to the first side wall of the first gate electrode 112a. The floating diffusion region (FD) may be doped with an N-type impurity.

The reset transistor (RG) 204a may be coupled to the floating diffusion region (FD) to discharge the floating diffusion region (FD). The reset transistor (RG) 204a may remove charges remaining in the floating diffusion region (FD) before photo charges in the photo diode (PD) 200 are transferred to the floating diffusion region (FD). One impurity region of the reset transistor (RG) 204a may be overlapped with the floating diffusion region (FD) and other impurity region may be electrically coupled to a power supply voltage (VDD).

In example embodiments, the reset transistor (RG) 204a may be of a buried channel type in which a buried channel is formed when the reset transistor (RG) 204a is turned on. When the reset transistor (RG) 204a is turned on, a channel may not be formed on the surface of the substrate 100 but formed apart from the surface of the substrate 100. In the reset transistor (RG) 204a, forming a buried channel described above, a second gate electrode 112b may be doped with an impurity having a different conductive type from a conductive type of an impurity in a first source/drain 136 formed on a portion of the substrate 100 away from both sides of the second gate electrode 112b. For example, the reset transistor (RG) 204a may include the second gate electrode 112b having a polysilicon doped with a P-type impurity.

Spacers 128 may be arranged on both side walls of the second gate electrode 112b. The first source/drain 136, doped with an N-type impurity, may be arranged on a portion of the substrate 100 away from both sides of the second gate electrode 112b. The first source/drain 136 may have a relatively lightly doped drain (LDD) scheme, where a relatively lightly doped N-type impurity region 124 is formed under the spacers 128 and a relatively heavily doped N-type impurity region 134 is formed under the surface of the substrate 100 away from the spacers 128. A hard mask pattern 120, which may include a silicon nitride or a silicon oxynitride, may be arranged on the second gate electrode 112b.

A channel region (not shown) may be arranged under the surface of the substrate 100 below the second gate electrode 112b. A second channel doping region 104 may be arranged on the channel region to control a threshold voltage of the reset transistor (RG) 204a. In example embodiments, the second channel doping region 104 may be doped with a P-type impurity. The structures of the reset transistor (RG) 204a, the drive transistor (SF) 204b, and the select transistor (ST) 204c illustrated in FIG. 3 may be substantially the same, and a buried-channel transistor 204 illustrated in FIG. 1 may be one of the reset transistor (RG) 204a, the drive transistor (SF) 204b, and the select transistor (ST) 204c.

The drive transistor (SF) 204b may be coupled to the floating diffusion region (FD) and may operate as a source follower. In example embodiments, the drive transistor (SF) 204b may be of a buried channel type, wherein a buried channel is formed when the drive transistor (SF) 204b is turned on. Therefore, the drive transistor (SF) 204b may have the same structure as the reset transistor (RG) 204a. A second gate electrode 112b may be doped with an impurity having a different conductive type from a conductive type of an impurity in a first source/drain 136 formed on a portion of the substrate 100 away from both sides of the second gate electrode 112b.

The select transistor (ST) 204c may be coupled to the drive transistor (SF) 204b in series and may activate the drive transistor (SF) 204b when a select signal is applied. In example embodiments, the select transistor (ST) 204c may be of a buried channel type, wherein a buried channel is formed when the select transistor (ST) 204c is turned on. Therefore, the select transistor (ST) 204c may have the same structure as the reset transistor (RG) 204a and the drive transistor (SF) 204b.

As described above, the transfer transistor (TG) 202, the reset transistor (RG) 204a, the drive transistor (SF) 204b and the select transistor (ST) 204c, formed in the active pixel region, have the first gate electrode 112a or the second gate electrode 112b including the polysilicon doped with a P-type impurity. In addition, the hard mask pattern 120 may be arranged on the first gate electrode 112a and the second gate electrode 112b. With this arrangement, processes to form the first gate electrode 112a and the second gate electrode 112b may be simplified because the first gate electrode 112a and the second gate electrode 112b, formed in the active pixel region, may be doped with an impurity having the same conductive type.

In addition, the reset transistor (RG) 204a, the drive transistor (SF) 204b and the select transistor (ST) 204c, formed in the active pixel region, may be of a buried channel type. Therefore, a flicker noise may be reduced because the buried channel may be formed apart from the defected surface of the substrate 100 when all of the reset transistor (RG) 204a, the drive transistor (SF) 204b and the select transistor (ST) 204c are turned on. If a channel is formed on the surface of the substrate 100, the amount of charges may vary each time because of the defect formed between the surface of the substrate 100 and the gate insulator 110, and a flicker noise may be caused. However, in example embodiments, a flicker noise may be reduced because the buried channel may be formed apart from the surface of the substrate 100 having relatively many defects.

In addition, a negative channel metal oxide semiconductor (NMOS) transistor 206 and a positive channel metal oxide semiconductor (PMOS) transistor 208 may be arranged in the peripheral circuit region of the substrate 100. The NMOS transistor 206 and the PMOS transistor 208 may be required to operate relatively fast. However, the NMOS transistor 206 and the PMOS transistor 208 may not be influenced much by a variance of the amount of charges each time because the NMOS transistor 206 and the PMOS transistor 208 may not be included in a pixel capturing an image. Therefore, the NMOS transistor 206 and the PMOS transistor 208 may be formed with transistors of a surface channel type, which have a relatively fast on/off operation.

More particularly, the NMOS transistor 206 in the peripheral circuit region may include a gate insulator 110, a third gate electrode 112c and a second source/drain 138. The third gate electrode 112c may include a polysilicon doped with an N-type impurity. Spacers 128 may be arranged on both side walls of the third gate electrode 112c. The second source/drain 138 may be doped with an impurity having a same conductive type, namely N-type, as a conductive type of an impurity in the third gate electrode 112c. The second source/drain 138 may have an LDD scheme, where a relatively lightly doped N-type impurity region 124 is formed under the spacers 128 and a relatively heavily doped N-type impurity region 132 is formed under the surface of the substrate 100 away from the spacers 128. In addition, a third channel doping region 106 may be arranged under the surface of a portion of the substrate 100 below the third gate electrode 112c to control a threshold voltage of the NMOS transistor 206. In example embodiments, the third channel doping region 106 may be doped with a P-type impurity.

A first metal silicide pattern 148a may be arranged on the third gate electrode 112c. In addition, a second metal silicide pattern 148b, including a same material as the first metal silicide pattern 148a, may be arranged on a portion of the substrate 100 on which the second source/drain 138 is arranged. The NMOS transistor 206 may operate relatively fast because of the silicide pattern 148a on the third gate electrode 112c and the silicide pattern 148b on the second source/drain 138.

The PMOS transistor 208 in the peripheral circuit region may include a gate insulator 110, a fourth gate electrode 112d and a third source/drain 146. The fourth gate electrode 112d may include a polysilicon doped with a P-type impurity. Spacers 128 may be arranged on both side walls of the fourth gate electrode 112d. The third source/drain 146 may be doped with an impurity having a same conductive type, namely P-type, as a conductive type of an impurity in the fourth gate electrode 112d. The third source/drain 146 may have an LDD scheme, where a relatively lightly doped P-type impurity region 126 is formed under the spacers 128 and a relatively heavily doped P-type impurity region 144 is formed under the surface of the substrate 100 away from the spacers 128. In addition, a fourth channel doping region 108 may be arranged under the surface of a portion of the substrate 100 below the fourth gate electrode 112d to control a threshold voltage of the PMOS transistor 208. In example embodiments, the fourth channel doping region 108 may be doped with an N-type impurity.

In addition, a first metal silicide pattern 148a may be arranged on the fourth gate electrode 112d and a second metal silicide pattern 148b may be arranged on a portion of the substrate 100 on which the third source/drain 146 is arranged. The first and second metal silicide patterns 148a and 148b of the PMOS transistor 208 may include the same material as the first and second metal silicide patterns 148a and 148b of the NMOS transistor 206.

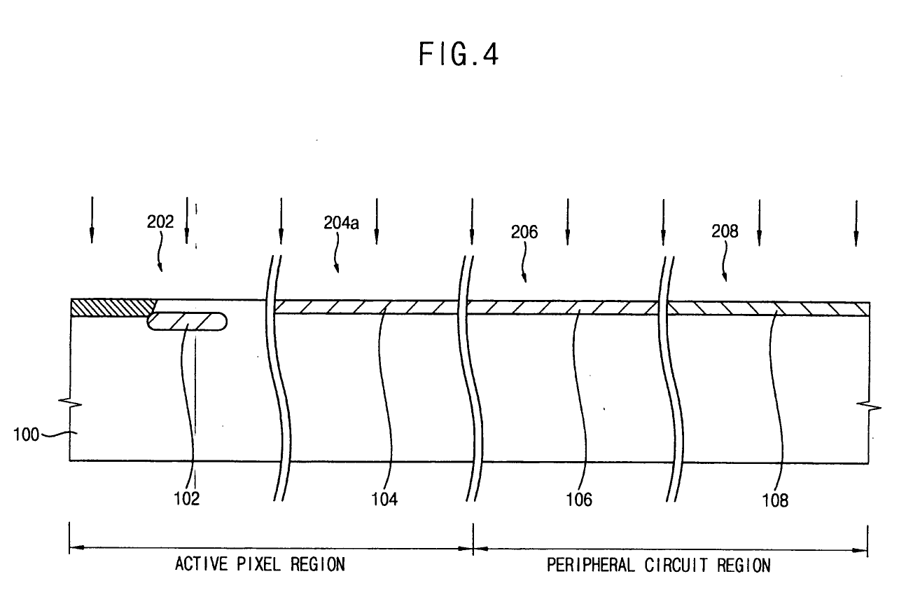

FIGS. 4 to 13 are cross-sectional views illustrating a method for manufacturing an image sensor according to example embodiments. Referring to FIG. 4, the substrate 100 may include the active pixel region where an image is captured and the peripheral circuit region to control and process an output signal from the active pixel region.

Each region of the substrate 100 may be divided into the active region and the device isolation region (not shown) by a device isolation process. The device isolation process may be performed by a shallow trench device isolation process or a local oxidation of silicon (LOCOS) process.

A first ion implantation mask pattern (not shown) may be formed to expose a portion of the substrate 100 on which the photo diode (PD) 200 (not shown in FIG. 4) is formed in the active pixel region. The photo diode (PD) 200 may be formed by doping an impurity into the substrate 100 using the first ion implantation mask pattern. The first ion implantation mask pattern and other ion implantation masks that will be described below may be formed by a photoresist pattern. The photo diode may include the first photo diode region (not shown) doped with a P-type impurity and the second photo diode region (not shown) doped with an N-type impurity on the first photo diode region. The second photo diode region may be extended to a portion of the substrate 100 on which the first side wall of the first gate electrode 112a (not shown in FIG. 4) of the transfer transistor (TG) 202 is arranged.

A second ion implantation mask pattern (not shown) may be formed to expose a portion of the substrate 100 on which the transfer transistor (TG) 202 is formed in the active pixel region. The first channel doping region 102 may be formed by doping a P-type impurity into a portion of the substrate 100 below the first gate electrode 112a of the transfer transistor (TG) 202 using the second ion implantation mask pattern. A third ion implantation mask pattern (not shown) may be formed to expose a portion of the substrate 100 on which the reset transistor (RG) 204a, the drive transistor (SF) 204b (not shown in FIG. 4) and the select transistor (ST) 204c (not shown in FIG. 4) are formed in the active pixel region. The second channel doping region 104 may be formed by doping a P-type impurity into a portion of the substrate 100 on which the reset transistor (RG) 204a, the drive transistor (SF) 204b and the select transistor (ST) 204c are formed using the third ion implantation mask pattern (not shown).

In addition, the third channel doping region 106 may be formed by doping a P-type impurity into a portion of the substrate 100 on which the NMOS transistor 206 is formed in the peripheral circuit region, and the fourth channel doping region 108 may be formed by doping an N-type impurity into a portion of the substrate 100 on which the PMOS transistor 208 is formed in the peripheral circuit region. Processes to form a fourth ion implantation mask pattern (not shown) and a fifth ion implantation mask pattern (not shown) are also required during the processes of forming the third channel doping region 106 and the fourth channel doping region 108.

As described above, the surface of the substrate 100 may be continuously damaged during the processes of ion-implanting to form the channel doping regions 102, 104, 106 and 108 and wells under the surface of the substrate 100. In addition, the surface of the substrate 100 in which an ion implantation is not required may be damaged because an ion implantation mask pattern should be formed and eliminated repeatedly. Therefore, the surface of the substrate 100 may have relatively more defects than a portion below the substrate 100 apart from the surface.

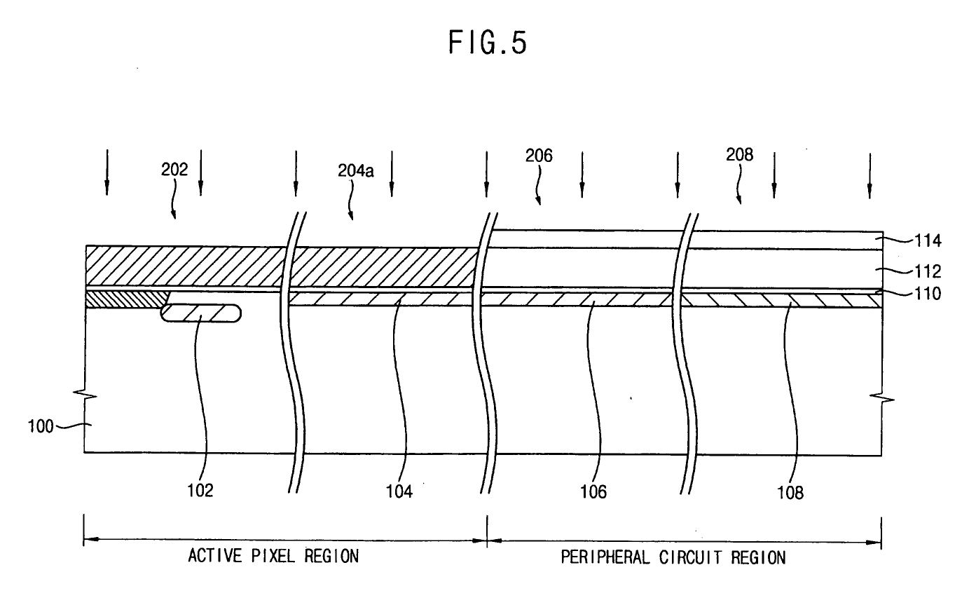

Referring to FIG. 5, the gate insulator 110 may be formed on the substrate 100. The gate insulator 110 may be formed by thermal oxidation of the substrate 100. An undoped polysilicon layer 112 may be arranged on the gate insulator 110. The polysilicon layer 112 may be formed by a low pressure chemical vapor deposition process. A sixth ion implantation mask pattern 114 may be formed to expose the polysilicon layer 112 formed in the active pixel region. The polysilicon layer 112 formed in the active pixel region may be selectively doped with a P-type impurity using the sixth ion implantation mask pattern 114. The P-type impurity may include boron.

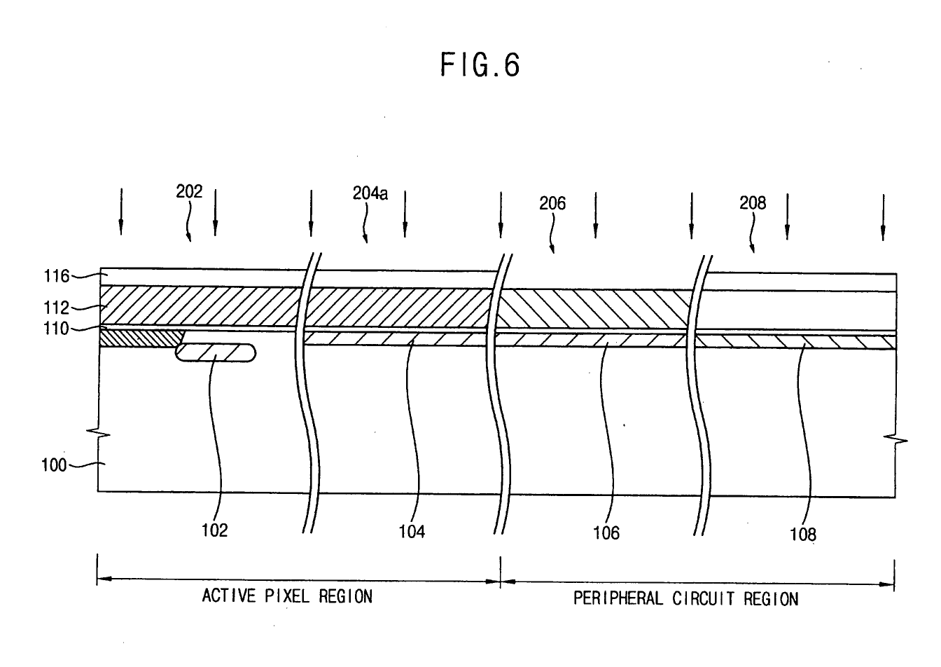

Referring to FIG. 6, a seventh ion implantation mask pattern 116 may be formed to expose a portion of the polysilicon layer 112 on which the NMOS transistor 206 is formed in the peripheral circuit region. The portion of the polysilicon layer 112 on which the NMOS transistor 206 is formed in the peripheral circuit region may be selectively doped with an N-type impurity using the seventh ion implantation mask pattern 116.

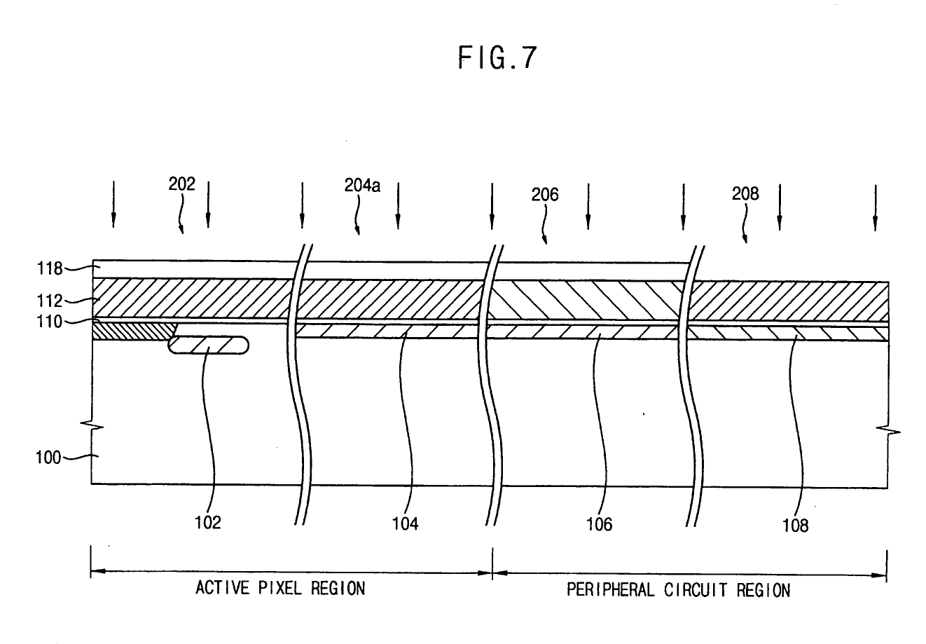

Referring to FIG. 7, an eighth ion implantation mask pattern 118 may be formed to expose a portion of the polysilicon layer 112 on which the PMOS transistor 208 is formed in the peripheral circuit region. The portion of the polysilicon layer 112 on which the PMOS transistor 208 is formed in the peripheral circuit region may be selectively doped with a P-type impurity using the eighth ion implantation mask pattern 118.

The impurity in the gate electrode 112d (not shown in FIG. 7) of the PMOS transistor 208 formed in the peripheral circuit region may have different energy and density from the energy and density of the impurity in the gate electrodes of the transistors formed in the active pixel region. Therefore, as described above, the process of ion-implanting into a portion of the polysilicon 112 on which the PMOS transistor 208 is formed in the peripheral circuit region and the process of ion-implanting into a portion of the polysilicon 112 on which the transistors are formed in the active pixel region may be performed separately. However, if the impurity in the gate electrode 112d of the PMOS transistor 208 formed in the peripheral circuit region has the same density as the density of the impurity in the electrodes of the transistors formed in the active pixel region, the process of ion-implanting into a portion of the polysilicon 112 on which the PMOS transistor 208 is formed in the peripheral circuit region and the process of ion-implanting into a portion of the polysilicon 112 on which the transistors are formed in the active pixel region may be performed simultaneously. In example embodiments, the process described with FIG. 7 may be omitted.

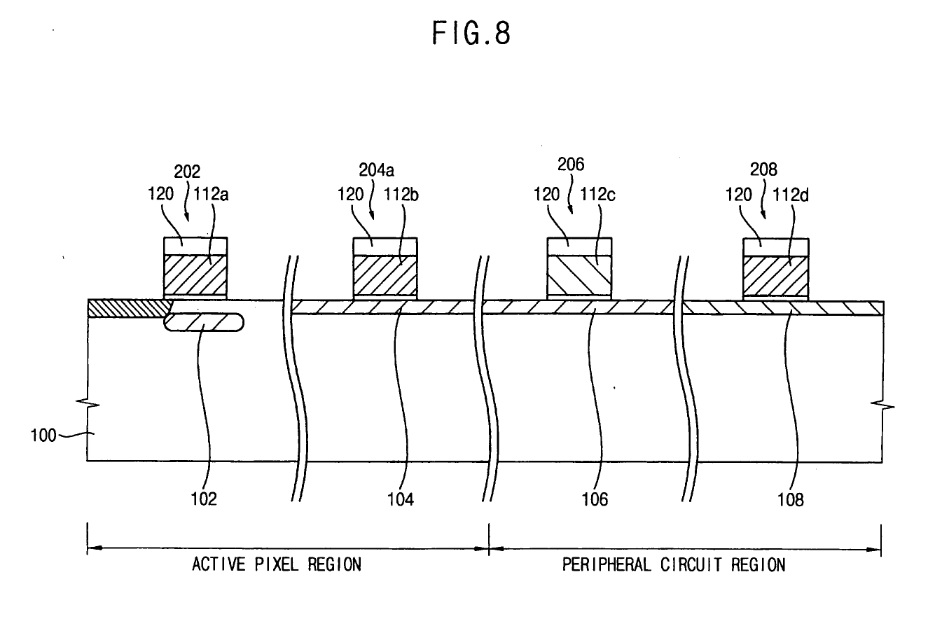

Referring to FIG. 8, a hard mask layer (not shown) may be formed on the polysilicon layer 112 doped with an impurity. The hard mask layer may be used as an anti-reflection layer in photolithography that will be performed later. The hard mask layer may be formed by depositing a silicon nitride or a silicon oxynitride on the polysilicon layer 112 by a chemical vapor deposition process.

A photoresist pattern may be formed on the hard mask layer by photolithography. The photoresist pattern masks regions on which the gate electrodes of the transistors in the active pixel region and the peripheral circuit region are formed. The hard mask pattern 120 may be formed by etching the hard mask layer using the photoresist pattern as an etching mask. The photoresist pattern may be eliminated by an ashing and strip process after the hard mask pattern 120 is formed.

The gate electrodes 112a, 112b, 112c and 112d of the transistors in the active pixel region and the peripheral circuit region may be formed by etching the polysilicon layer 112 using the hard mask pattern 120 as an etching mask. As shown, the gate electrode 112a of the transfer transistor (TG) 202 and the gate electrodes 112b of the reset transistor (RG) 204a, the drive transistor (SF) 204b and the select transistor (ST) 204c in the active pixel region include a polysilicon doped with a P-type impurity. The gate electrode 112c of the NMOS transistor 206 in the peripheral circuit region may include a polysilicon doped with an N-type impurity and the gate electrode 112d of the PMOS transistor 208 in the peripheral circuit region may include a polysilicon doped with a P-type impurity. The gate electrode of the transfer transistor (TG) 202 will be referred to as the first gate electrode 112a, the gate electrodes of the reset transistor (RG) 204a, the drive transistor (SF) 204b and the select transistor (ST) 204c will be referred to as the second gate electrode 112b, the gate electrode of the NMOS transistor 206 in the peripheral circuit region will be referred to as the third gate electrode 112c, and the gate electrode of the PMOS transistor 208 in the peripheral circuit region will be referred to as the fourth gate electrode 112d.

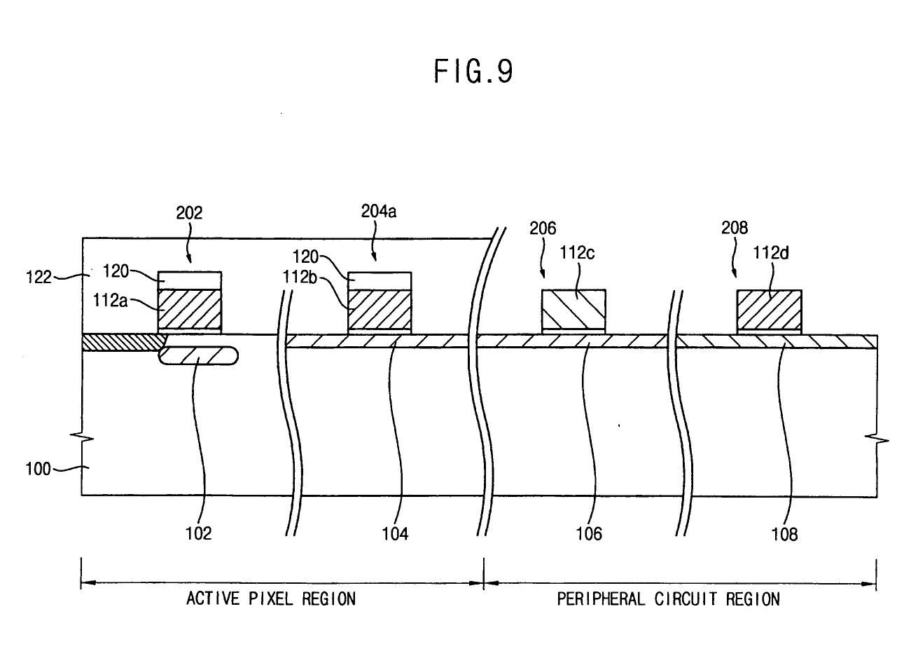

Referring to FIG. 9, a photoresist pattern 122, covering the active pixel region of the substrate 100, may be formed to selectively expose the peripheral circuit region of the substrate 100. The hard mask pattern 120 on the third gate electrode 112c and the fourth gate electrode 112d may be eliminated using the photoresist pattern 122 as an etching mask. A wet etching process or a dry etching process may be used to eliminate the hard mask pattern 120, for example, the wet etching process because the substrate 100 may be damaged during the dry etching process. Only the hard mask pattern 120 on the first gate electrode 112a and the second gate electrode 112b remains after the etching process described above. The photoresist pattern 122 may be eliminated by an ashing and strip process.

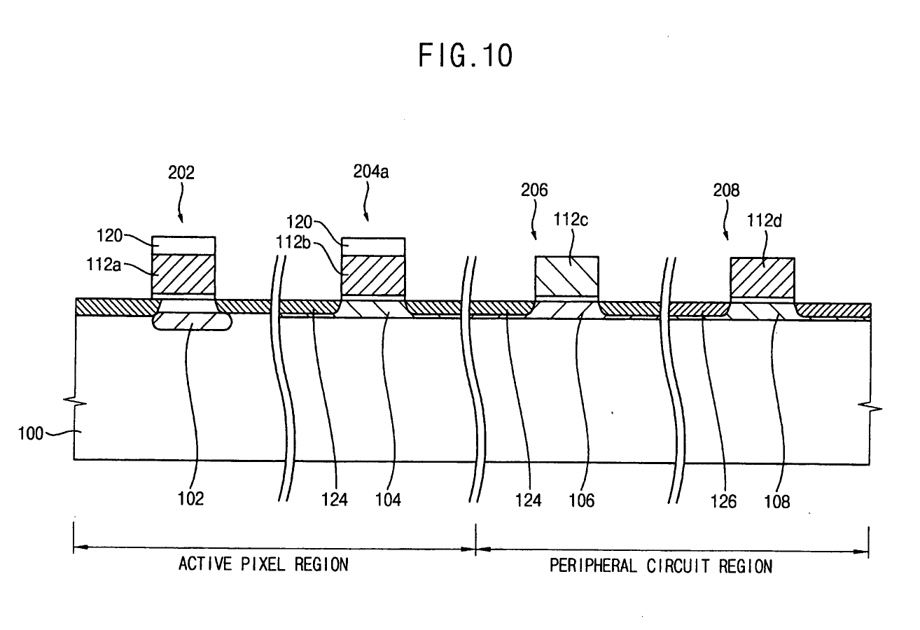

Referring to FIG. 10, a ninth ion implantation mask pattern (not shown) may be formed to selectively expose a portion of the substrate 100 away from one side of the first gate electrode 112a, both sides of the second gate electrode 112b in the active pixel region, and both sides of the third gate electrode 112c in the peripheral circuit region. A lightly doped N-type impurity region 124 may be formed on a portion of the substrate 100 away from one side of the first gate electrode 112a and both sides of the second and third gate electrodes 112b and 112c by ion-implanting an N-type impurity into the substrate 100 using the ninth ion implantation mask pattern.

In addition, a tenth ion implantation mask pattern (not shown) may be formed to selectively expose a portion of the substrate 100 away from both sides of the fourth gate electrode 112d in the peripheral circuit region. A lightly doped P-type impurity region 126 may be formed on a portion of the substrate 100 away from both sides of the fourth gate electrodes 112d by ion-implanting a P-type impurity into the substrate 100 using the tenth ion implantation mask pattern.

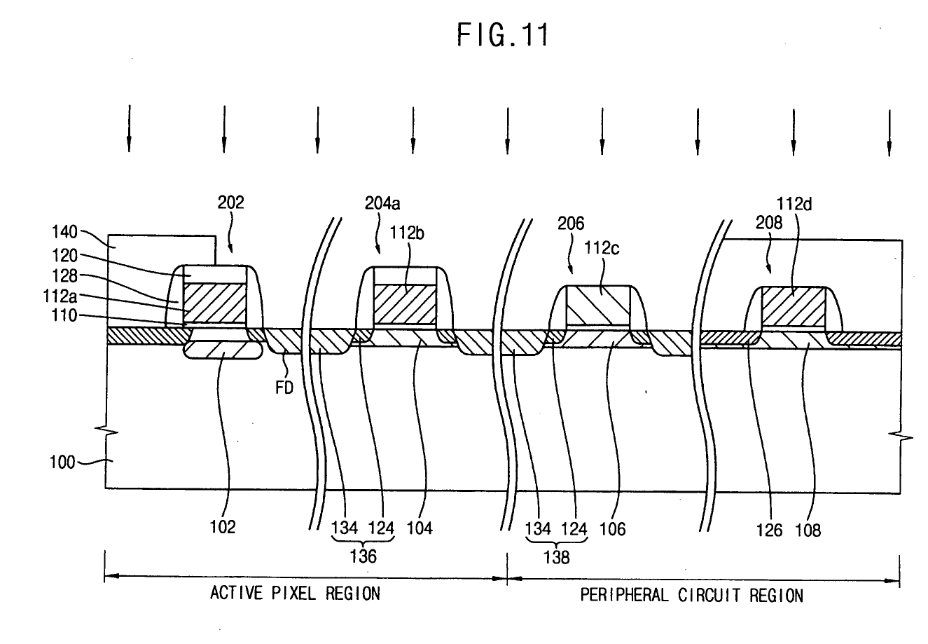

Referring to FIG. 11, an insulator (not shown) for spacers may be formed on the surface of the substrate 100, the hard mask pattern 120, the first gate electrode 112a, the second gate electrode 112b, the third gate electrode 112c and the fourth gate electrode 112d. The insulator for spacers may be formed by depositing a silicon nitride. The spacers 128 may be formed on the side wall of the gate electrodes 112a, 112b, 112c and 112d by anisotropically etching the insulator for spacers.

An eleventh ion implantation mask pattern 140 may be formed to selectively expose a portion of the substrate 100 away from one side of the first gate electrode 112a and both sides of the second gate electrode 112b in the active pixel region, and both sides of the third gate electrode 112c in the peripheral circuit region. Heavily doped N-type impurity regions 134, adjacent to the lightly doped N-type impurity regions 124, may be formed on a portion of the substrate 100 away from one side of the first gate electrode 112a and both sides of the second and third gate electrodes 112b and 112c by ion-implanting an N-type impurity into the substrate 100 using the eleventh ion implantation mask pattern 140, thereby forming first and second source/drain regions 136 and 138, respectively.

During the process described above, the first and second gate electrodes 112a and 112b may not be doped with the N-type impurity because the hard mask pattern 120 remains on the first and second gate electrodes 112a and 112b. Therefore, the first and second gate electrodes 112a and 112b may include a polysilicon doped with a P-type impurity. On the other hand, the third gate electrode 112c, as well as the exposed substrate, may be doped with the N-type impurity during the process described above, because there is not a hard mask pattern on the third gate electrode 112c.

The buried-channel transistors in the active pixel region may be achieved by performing the processes described above. The buried-channel transistors may include a gate having a polysilicon doped with a P-type impurity, and the first source/drain 136 having a lightly doped drain (LDD) scheme and doped with an N-type impurity. In addition, the NMOS transistor formed in the peripheral circuit region may have a surface channel when the NMOS transistor is turned on, and may include a gate having a polysilicon doped with an N-type impurity, and the second source/drain 138 having a lightly doped drain (LDD) scheme and doped with an N-type impurity.

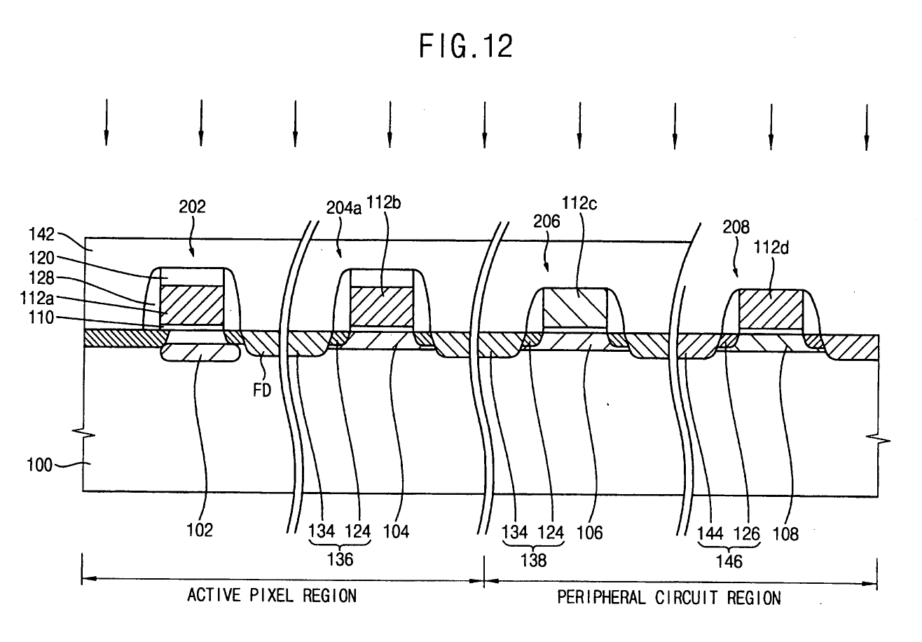

Referring to FIG. 12, a twelfth ion implantation mask pattern 142 may be formed to selectively expose a portion of the substrate 100 away from both sides of the fourth gate electrode 112d in the peripheral circuit region. Heavily doped P-type impurity region 144, adjacent to the lightly doped P-type impurity region 126, may be formed on a portion of the substrate 100 away from both sides of the fourth gate electrode 112d by ion-implanting a P-type impurity into the substrate 100 using the twelfth ion implantation mask pattern 142, thereby forming a third source/drain region 146. The PMOS transistor formed in the peripheral circuit region may include a fourth gate electrode 112d having a polysilicon doped with a P-type impurity and the third source/drain 146 having a lightly doped drain (LDD) scheme and doped with a P-type impurity.

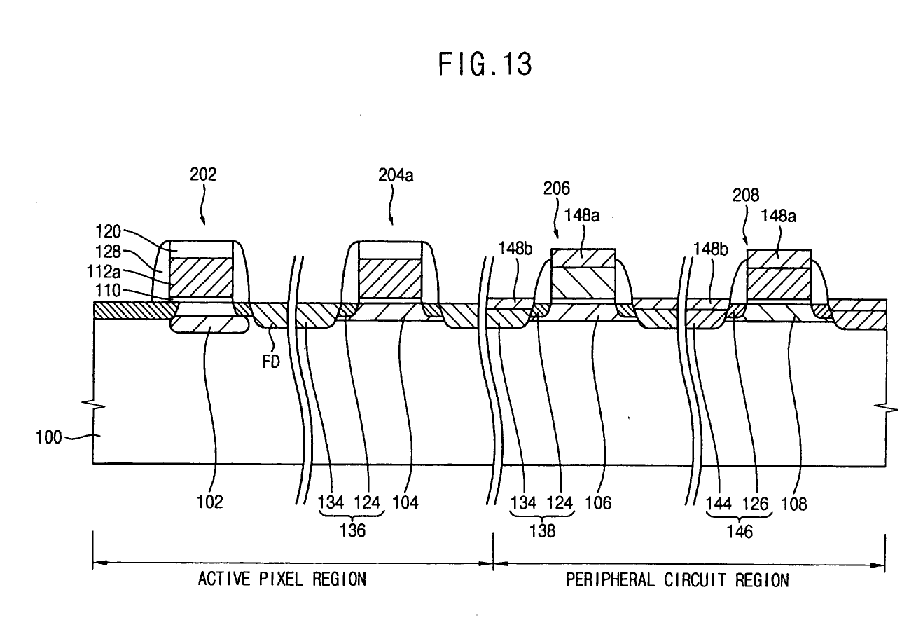

Referring to FIG. 13, an anti-silicidation layer (not shown) may be formed on the surface of the substrate 100, the spacers 128, the hard mask pattern 120, the third gate electrode 112c and the fourth gate electrode 112d. The anti-silicidation layer may be formed by depositing a silicon nitride by a chemical vapor deposition process. A photoresist pattern (not shown) covering the active pixel region may be formed, and an anti-silicidation pattern (not shown) may be formed by etching the anti-silicidation layer formed in the peripheral circuit region using the photoresist pattern as an etching mask.

A metal layer (not shown) to form a silicide pattern may be formed on the surface of the anti-silicidation pattern, the peripheral circuit region of the substrate 100, the spacers 128, the third gate electrode 112c and the fourth gate electrode 112d. The metal layer may include cobalt or nickel.

The first and second metal silicide patterns 148a and 148b may be formed by causing the metal layer to react with silicon materials under the metal layer by heating the substrate 100 having the metal layer. The first and second metal silicide patterns 148a and 148b may be formed on the third and fourth gate electrodes 112c and 112d and on the exposed substrate 100, namely, on the second and third source/drain 138 and 146. However, a metal silicide pattern may not be formed on the spacers 128 and on the anti-silicidation pattern (not shown) because there are not silicon materials under the metal layer. The unreacted metal layer (not shown) may be eliminated after the first and second metal silicide patterns 148a and 148b are formed.

By performing the processes described above, a CMOS image device may be achieved, where the CMOS image device includes transistors of a buried channel type in the active pixel region and transistors of a surface channel type in the peripheral circuit region. In addition, only transistors in the peripheral circuit region may include a metal silicide pattern.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of example embodiments. Accordingly, all such modifications are intended to be included within the scope of example embodiments as defined in the claims. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

1-14. (canceled)

15. A method for manufacturing an image sensor, comprising:
forming a photo diode by doping an impurity into a portion of a substrate;
forming a gate insulator on the substrate;
forming a polysilicon layer on the gate insulator;
doping a P-type impurity into a portion of the polysilicon layer;
forming a first hard mask pattern on the polysilicon layer;
forming gate electrodes of a transfer transistor and buried-channel transistors by etching the polysilicon layer doped with a P-type impurity using the first hard mask pattern as an etching mask, each of the buried-channel transistors having a buried channel; and
forming a first source/drain by doping an N-type impurity into the substrate away from both sides of the gate electrodes of the buried-channel transistors using the first hard mask pattern as an ion implantation mask.

16. The method of claim 15, further comprising:
forming spacers along sidewalls of the gate insulator, the gate electrodes and the first hard mask pattern.

17. The image sensor of claim 16, wherein forming the first source/drain region comprises:
forming a lightly doped N-type impurity region under the spacers; and
forming a heavily doped N-type impurity region under the surface of the substrate away from the spacers.

18. The method of claim 15, further comprising:
forming a channel doping region on the buried channel of the buried-channel transistors by ion-implanting an impurity into the substrate to control a threshold voltage.

19. The method of claim 15, further comprising:
forming a negative channel metal oxide semiconductor (NMOS) transistor and a positive channel metal oxide semiconductor (PMOS) transistor of a surface channel type in a peripheral circuit region, where the substrate is divided into an active pixel region and the peripheral circuit region.

20. The method of claim 19, wherein forming the NMOS transistor and the PMOS transistor includes:
selectively ion-implanting an N-type impurity into a portion of the polysilicon layer on which the NMOS transistor is formed in the peripheral circuit region;
forming a second hard mask pattern on the polysilicon layer in the peripheral circuit region;
forming a gate electrode of the NMOS transistor doped with an N-type impurity and a gate electrode of the PMOS transistor doped with a P-type impurity by etching the polysilicon layer using the second hard mask pattern as an etching mask;
forming a second source/drain by doping an N-type impurity into the substrate away from both sides of the gate electrode of the NMOS transistor; and
forming a third source/drain by doping a P-type impurity into the substrate away from both sides of the gate electrode of the PMOS transistor.

21. The method of claim 20, wherein the second hard mask pattern and the first hard mask pattern are formed simultaneously, and
the gate electrodes of the NMOS transistor, the PMOS transistor, the transfer transistor and the buried-channel transistors are formed simultaneously.

22. The method of claim 20, further comprising:
selectively eliminating the second hard mask pattern formed on the gate electrodes of the NMOS transistor and the PMOS transistor.

23. The method of claim 20, further comprising:
forming a first metal silicide pattern on the gate electrodes of the NMOS transistor and the PMOS transistor; and
forming a second metal silicide pattern on the second source/drain and the third source/drain.

24. The method of claim 23, wherein the first and second metal silicide patterns are made of the same material.

25. The method of claim 23, further comprising:
forming spacers along sidewalls of the gate insulator, the gate electrodes and a portion of the first metal silicide pattern.

26. The method of claim 25, wherein forming the second and third source/drain regions comprises:
forming a lightly doped N-type impurity region under the spacers; and
forming a heavily doped N-type impurity region under the second metal silicide pattern.

27. The method of claim 23, further comprising:
forming channel doping regions under the gate electrodes being doped with an impurity to control a threshold voltage.

28. A method for manufacturing an image sensor, comprising:
forming a photo diode by doping an impurity into a portion of an active pixel region of a substrate;
forming a gate insulator on the substrate;
forming a polysilicon layer on the gate insulator;
ion-implanting a P-type impurity into a portion of the polysilicon layer on which a transistor is formed in the active pixel region and into a portion of the polysilicon layer on which a positive channel metal oxide semiconductor (PMOS) transistor is formed in a peripheral circuit region;
ion-implanting an N-type impurity into a portion of the polysilicon layer on which a negative channel metal oxide semiconductor (NMOS) transistor is formed in the peripheral circuit region;
forming gate electrodes of a transfer transistor and buried-channel transistors in the active pixel region and gate electrodes of the NMOS transistor and the PMOS transistor in the peripheral circuit region by patterning the polysilicon layer, each of the buried-channel transistors having a buried channel;
forming a first source/drain and a second source/drain by selectively doping an N-type impurity into the substrate away from both sides of the gate electrodes of the buried-channel transistors and into the substrate away from both sides of the gate electrode of the NMOS transistor respectively; and
forming a third source/drain by doping selectively a P-type impurity into the substrate away from both sides of the gate electrode of the PMOS transistor.

29. The method of claim 28, further comprising:
forming a hard mask pattern on the polysilicon layer.

30. The method of claim 29, further comprising:
selectively eliminating the hard mask pattern formed on the gate electrodes of the NMOS transistor and the PMOS transistor after forming the gate electrodes using the hard mask pattern.

31. The method of claim 30, wherein selectively eliminating the hard mask pattern includes:
forming a first photoresist pattern covering the active pixel region; and
etching the hard mask pattern in the peripheral circuit region using the first photoresist pattern as an etching mask.

32. The method of claim 28, wherein forming the first source/drain and the second source/drain includes:
forming a second photoresist pattern selectively exposing the substrate away from both sides of the gate electrodes of the transfer transistor, the buried-channel transistors and the NMOS transistor; and
ion-implanting an impurity into the substrate using the second photoresist pattern as an ion implantation mask.
